(19) United States
(12) Patent Application Publication
(10) Pub. No.: US 2012/0017435 A1
(43) Pub. Date: Jan. 26, 2012

(54) Method of manufacturing PCB having electronic components embedded therein

(75) Inventors: Seung Hyun Sohn, Suwon-si (KR); Yul Kyo Chung, Yongin-si (KR); Byoung Chan Kim, Cheongju-si (KR); Moon Il Kim, Suwon-si (KR); Kwan Kyu Kim, Seocheon-gun (KR); Yee Na Shin, Seoul (KR)

(73) Assignee: SAMSUNG ELECTRO-MECHANICS CO., LTD, Suwon (KR)

(21) Appl. No.: 13/200,983

(22) Filed: Oct. 6, 2011

Related U.S. Application Data
(62) Division of application No. 12/215,414, filed on Jun. 27, 2008.

(30) Foreign Application Priority Data
May 9, 2008 (KR) 10-2008-0043185

(51) Int. Cl. H05K 3/30

(52) U.S. Cl. 29/832

(57) ABSTRACT

A method of manufacturing a PCB having electronic components embedded therein, including: preparing a copper foil layer including a thin copper foil coated with a resin layer; fixing electronic components onto the resin layer; forming a core layer in which the electronic components are embedded; forming internal layer circuits which are electrically connected to the electronic components; forming an insulating layer on the internal layer circuits; and forming external layer circuits on the insulating layer such that the external layer circuits are electrically connected to the internal layer circuits.

### CROSS-REFERENCE TO RELATED APPLICATIONS

This application is a U.S. divisional application filed under 37 CFR 1.53(b) claiming priority benefit of U.S. Ser. No. 12/215,414 filed in the United States on Jun. 27, 2008, which claims earlier priority benefit to Korean Patent Application No. 10-2008-0043185 filed with the Korean Intellectual Property Office on May 9, 2008 the disclosures of which are incorporated herein by reference.

### BACKGROUND

1. Field

The present invention relates to a printed circuit board (PCB) having electronic components embedded therein and a method of manufacturing the same.

2. Description of the Related Art

Recently, as mobile terminals and notebooks come in wide use, electronic equipments required for a high-speed operation are widely used. Accordingly, PCBs capable of performing a high-speed operation are required.

For such a high-speed operation, high-density wiring lines and electronic parts are needed.

To implement such high-density wiring lines and electronic parts, a circuit miniaturization process such as semi-additive process (SAP) and modified semi-additive process (MSAP) is applied as a build-up process or circuit forming process.

Further, embedded PCBs in which electronic components such as resistors, capacitors, or ICs are embedded have been developed.

In the embedded PCB, resistors, capacitors, or capacitors and IC packages are formed outside the PCB or in the internal layer thereof by using new a material or process.

The most important feature of the embedded PCB is that the size thereof can be reduced, a surface-mounting area can be additionally secured, and an I/O area for electrical interconnection can be secured, because chips are embedded in the PCB.

In the conventional embedded PCB, however, circuits which are connected to I/O terminals for electrical interconnection of electronic components cannot be formed in a core layer composed of prepreg, in which electronic components such as ICs and chips are embedded. Therefore, a primary insulating layer should be laminated on the core layer having the electronic components embedded therein, and internal layer circuits which are electrically connected to the I/O terminals of the electronic components should be formed on the insulating layer.

Further, a secondary insulating layer should be formed on the primary insulating layer, and external layer circuits which are electrically connected to the internal layer circuits formed on the primary insulating layer should be formed in such a manner that circuit patterns of the internal layer circuits connected to the I/O terminals of the electronic components are redistributed and solder balls for external connection are formed on the PCB.

Therefore, when the electronic components are embedded in the conventional embedded PCB, at least 6 circuit layers which are laminated on and under the core layer having the electronic components embedded therein should be formed.

In other word, there is a limit in reducing the number of layers in the conventional embedded PCB. Therefore, it is difficult to simplify the manufacturing process and to enhance productivity.

Further, when cavities are formed in the core layer and the electronic components are fixed to the cavities so as to embed the electronic components in the core layer of the conventional embedded PCB, the opposite surface to the surface where the I/O terminals of the electronic components are formed should be used. Therefore, when a plurality of electronic components are embedded in the PCB, it is difficult to secure the distribution area of the internal layer circuits and the external layer circuits for electrical interconnection of the I/O terminals of the electronic components. Therefore, there are difficulties in achieving high integration and high density.

### SUMMARY

An advantage of the present invention is that it provides a PCB having electronic components embedded therein and a method of manufacturing the same, in which the number of layers of the PCB can be reduced to thereby simplify the manufacturing process and to achieve mass production.

Additional aspects and advantages of the present general inventive concept will be set forth in part in the description which follows and, in part, will be obvious from the description, or may be learned by practice of the general inventive concept.

According to an aspect of the invention, a PCB having electronic components embedded therein comprises a core layer having electronic components embedded therein and a resin layer formed thereon and thereunder; internal layer circuits formed on the resin layer and being electrically connected to the electronic components; an insulating layer formed on the internal layer circuits; and external layer circuits formed on the insulating layer and being electrically connected to the internal layer circuits.

Preferably, the core layer is formed of an insulating material. That is, the core layer may be formed of prepreg.

The internal layer circuits may be formed by a semi additive process (SAP). Alternatively, the internal layer circuits may be formed by a modified semi additive process (MSAP).

The PCB may further include conductive vias that electrically connect the internal layer circuits formed on the resin layers, respectively.

According to another aspect of the invention, a method of manufacturing a PCB having electronic components embedded therein comprises: preparing a copper foil layer including a thin copper foil coated with a resin layer; fixing electronic components onto the resin layer; forming a core layer in which the electronic components are embedded; forming internal layer circuits which are electrically connected to the electronic components; forming an insulating layer on the internal layer circuits; and forming external layer circuits on the insulating layer such that the external layer circuits are electrically connected to the internal layer circuits.

The copper foil layer may include a carrier copper foil for facilitating handling and the thin copper foil which is formed on the carrier copper foil and is coated with the resin layer.

The electronic components may be fixed onto the resin layer of the copper foil layer through a bonding method using die bonder.

The forming of the core layer may include: laminating an insulating material on the resin layer, the insulating material having cavities corresponding to the electronic components; and laminating another copper foil layer corresponding to the copper foil layer on the insulating material such that the electronic components are buried by the insulating material.

The insulating material may be formed of prepreg.

The forming of the internal layer circuits may include: removing the thin copper foil; and forming the internal layer circuits on the resin layer through SAP such that the internal layer circuits are electrically connected to the electronic components.

Alternatively, the forming of the internal layer circuits may include forming the internal layer circuits on the resin layer through MSAP by using the thin copper foil such that the internal layer circuits are electrically connected to the electronic components.

The forming of the internal layer circuits may further include forming conductive vias which electrically connect the internal layer circuits which are positioned in different layers.

The method may further comprise: forming a protective layer on the insulating layer, the protective layer serving to protect the external layer circuits, after the forming of the external layer circuits; and forming external connection portions which are electrically connected to the external layer circuits.

The protective layer may be formed of solder resist.

The forming of the external connection portions may include: exposing the external layer circuits to the outside of the protective layer, the external layer circuits being electrically connected to the external connection portions; and forming the external connection portions on the external layer circuits exposed to the outside of the protective layer.

The external connection portions may include solder bumps.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a PCB having electronic components embedded therein according to an embodiment of the invention; and

FIGS. 2 to 12 are process diagrams sequentially showing a method of manufacturing a PCB having electronic components embedded therein according to an embodiment of the invention.

### DESCRIPTION OF EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a PCB having electronic components embedded therein and a method of manufacturing the same according to the present invention will be described in detail with reference to the accompanying drawings.

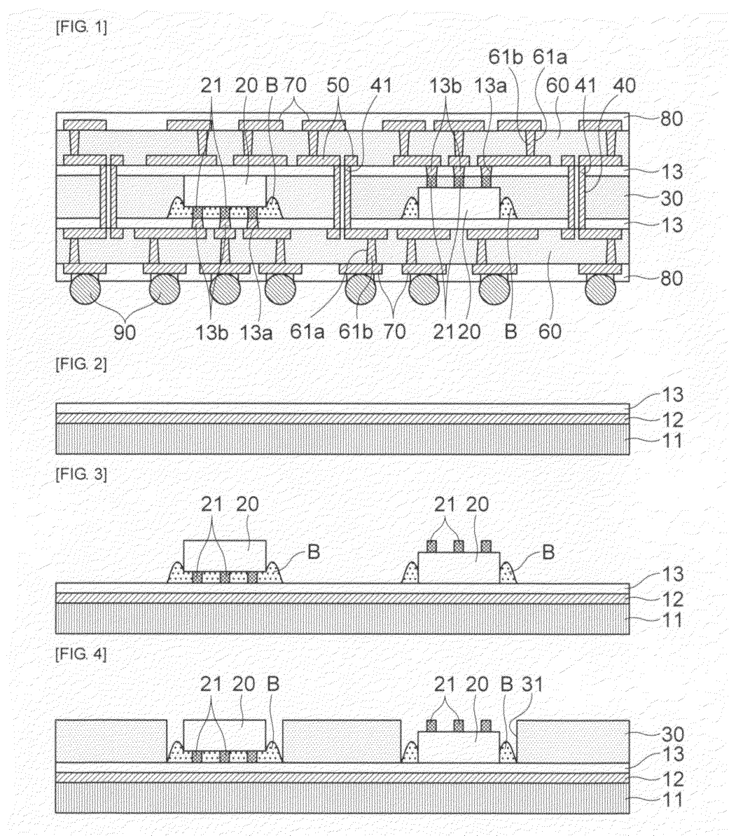

FIG. 1 is a cross-sectional view of a PCB having electronic components embedded therein according to an embodiment of the invention. FIGS. 2 to 12 are process diagrams sequentially showing a method of manufacturing a PCB having electronic components embedded therein according to an embodiment of the invention.

Referring to FIGS. 1 to 12, the PCB having electronic components embedded therein according to the embodiment of the invention will be described.

As shown in FIG. 1, the PCB having electronic components embedded therein includes a core layer 30 having electronic components 20 embedded therein and a resin layer 13 formed thereon and thereunder, respectively; internal layer circuits 50 which are formed on the resin layer 13 so as to be electrically connected to the electronic components 20; an insulating layer 60 formed on the internal layer circuits 50; and external layer circuits 70 which are formed on the insulating layer 60 so as to be electrically connected to the internal layer circuits 50.

Preferably, the core layer 30 is formed of an insulating material. For example, the core layer 30 may be formed of prepreg which can be electrically insulated and is easy to handle.

The electronic components 20 may be fixed onto the resin layer 13 through a bonding method using die bonder B.

That is, the electronic components 20 may be fixed onto the resin layer 13 through the die bonder B before being buried in the core layer 30.

Further, the internal layer circuits 50 may be formed through an electroless plating or electroplating method using ASP.

Further, the internal layer circuits 50 may be formed through an electroless plating or electroplating method using MASP.

Meanwhile, the PCB having electronic components embedded therein may further include conductive vias 40 and 41 which electrically connect the internal circuits 50 formed on the resin layers 13, respectively.

In this case, the conductive vias 40 and 41 may be a through-hole 40 passing through the resin layers 13 and the core layer 30 and a conductive material 41 filled in the through-hole 40, that is, metal.

I/O terminals of the electronic components 20 can be electrically connected to the internal layer circuits 50 through conductive vias 13a and 13b which are formed in the resin layer 13 so as to correspond to the I/O terminals of the electronic components 20.

The conductive vias 13a and 13b may be composed of through-holes 13a, which are formed in the resin layer 13 so as to correspond to the I/O terminals 21 of the electronic components 20, and a conductive material 13b filled in the through-holes 13a, that is, metal.

The internal layer circuits 50 and the external layer circuits 70 may be electrically connected to each other through conductive vias 61a and 61b formed in the insulating layer 60.

That is, through-holes 61a are formed in the insulating layer 60 so as to correspond to the internal layer circuits 50, and are then filled with a conductive material 61b such that the internal layer circuits 50 and the external circuits 70 can be electrically connected to each other through the conductive material 61b.

Meanwhile, the PCB having electronic components embedded therein may further include a protective layer 80 which is formed on the insulating layer 60 so as to protect the insulating layer 60 and the external layer circuits 70.

That is, such a material as solder resist is applied as the protective layer 80 on the insulating layer 60, thereby protecting the insulating layer 60 and the external circuits 70 from outside.

To mount or install the PCB on an external device, external connection portions 90 such as solder bumps may be further formed on the external layer circuits 70.

In this case, portions of the protective layer 80 where the external connection portions 90 are to be formed may be exposed by an etching process such that the external connection portions 90 can be electrically connected to the external circuits 70.

Next, a method of manufacturing a PCB having electronic components embedded therein according to the embodiment of the invention will be described.

The method of manufacturing a PCB having electronic components embedded therein according to the embodiment of the invention includes: preparing a copper foil layer including a thin copper foil 12 coated with a resin layer 13; fixing electronic components 20 onto the resin layer 13; forming a core layer 30 in which the electronic components 20 are embedded; forming internal layer circuits 50 which are electrically connected to the electronic components 20; forming an insulating layer 60 on the internal layer circuits 50; and forming external layer circuits 70 which are formed on the insulating layer 60 so as to be electrically connected to the internal layer circuits 50.

More specifically, as shown in FIG. 2, the copper foil layer is prepared, including a carrier copper foil 11 for facilitating handling and the thin copper foil 12 which is formed on the carrier copper foil 11 and is coated with the resin layer 13.

The reason why the resin layer 13 is not directly applied on the carrier copper foil 11 but is applied on the thin copper foil 12 is as follows. The carrier copper foil 11 has larger roughness than the thin copper foil 12. Therefore, when the resin layer 13 is directly applied on the carrier copper foil 11, it is difficult to form the resin layer 13 in the form of thin film. Further, it is difficult to form the resin layer 13 with high flatness.

Therefore, when the resin layer 13 is applied on the thin copper foil 12 after the thin copper foil 12 is formed on the carrier copper foil 11, the resin layer 13 can be formed with a small thickness as possible, which makes it possible to achieve a reduction in thickness of the PCB.

Next, as shown in FIG. 3, the electronic components 20 are mounted at constant intervals on the resin layer 13.

At this time, the electronic components 20 may be fixed by a bonding method using die bonder B.

Further, It is preferable that when the plurality of electronic components 20 are mounted, the I/O terminals 21 of one electronic component 20 are directed to the reverse direction to those of the adjacent electronic component 20, in order to increase distribution efficiency of the circuit patterns of the I/O terminals.

Then, as shown in FIG. 4, the core layer 30 is formed, which has cavities 31 formed in positions corresponding to the electronic components 20.

That is, the core layer 30 which is formed of prepreg and has cavities 31 formed in positions corresponding to the electronic components 20 is laminated on the resin layer 13 such that the electronic components 20 are positioned in the cavities 31, respectively.

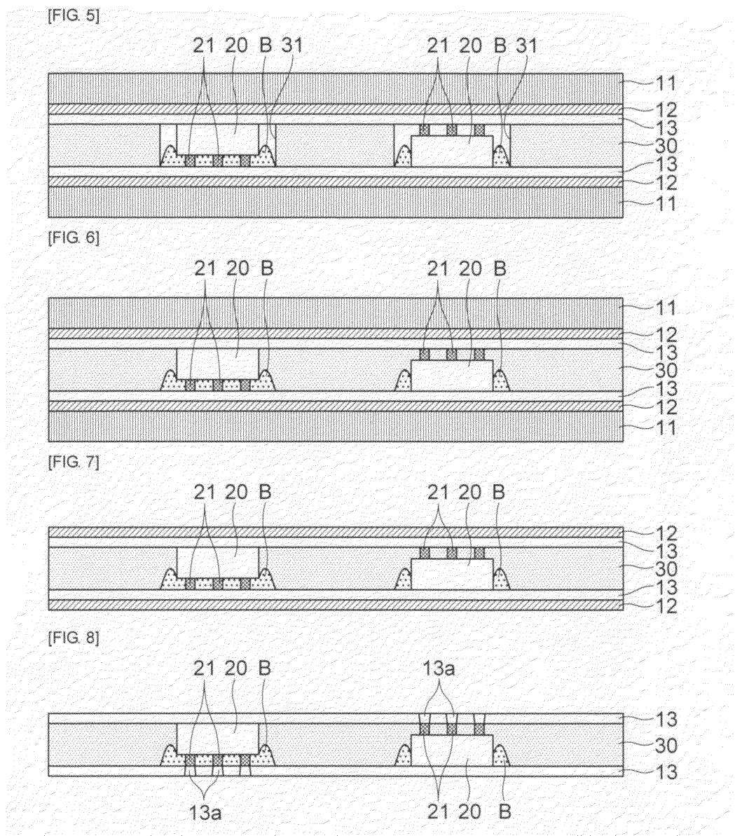

Next, as shown in FIG. 5, another copper foil layer having the same shape as the above-described copper foil layer is laminated on the core layer 30.

At this time, the copper foil layer is laminated on the core layer 30 such that the resin layer 13 is contacted with the core layer 30.

Then, as shown in FIG. 6, when predetermined heat and pressure are applied to the core layer 30 and the copper foil layers laminated on and under the core layer 30 through a vacuum lamination process, the cavities 31 formed in the core layer 30 are filled with the prepreg composing the core layer 30 such that the electronic components 20 can be completely buried by the core layer 30.

Subsequently, as shown in FIG. 7, the carrier copper foils 11 of the copper foil layers laminated on and under the core layer 30 are removed.

Then, as shown in FIG. 8, the thin copper foils 12 of the copper foil layers are removed, and through-holes 13a are formed in the resin layers 13 laminated on and under the core layer 30 such that the I/O terminals 21 of the electronic components 20 are exposed.

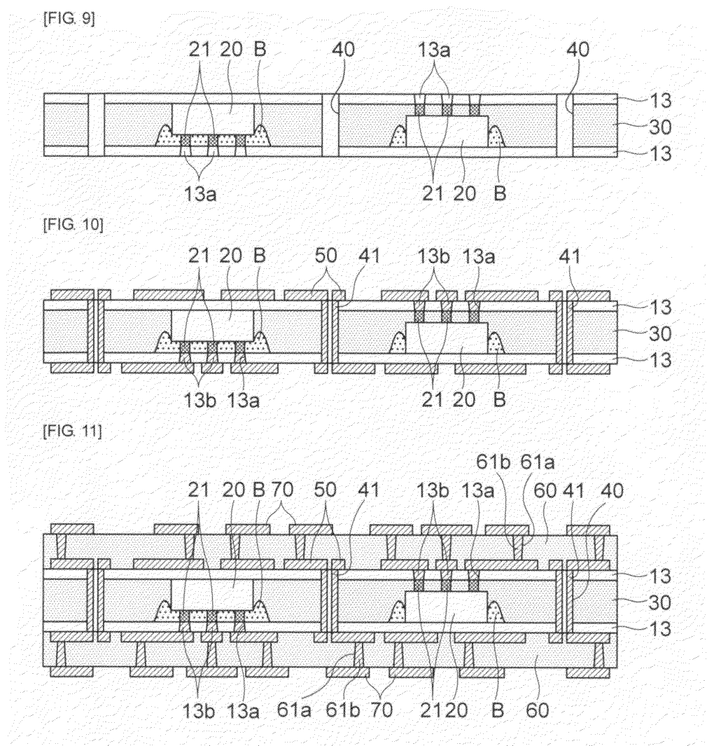

Further, as shown in FIG. 9, through-holes 40 are formed in such a manner that the resin layers 13 laminated on and under the core layer 30 communicate with each other.

Next, as shown in FIG. 10, conductive materials 13b and 41 are filled or formed in the through-holes 13a and 40, thereby forming electrical connection paths.

Then, the internal layer circuits 50 are formed on the resin layers 13, respectively, through an electroless plating or electroplating method using SAP, the internal layer circuits 50 being electrically connected to the electronic components 20 and constructing predetermined circuit patterns.

Subsequently, as shown in FIG. 11, the insulating layer 60 is formed on the internal layer circuits 50.

That is, the insulating layer 60 formed of an insulating material is laminated on the resin layer 13 so as to cover the internal layer circuits 50.

Further, conductive vias are formed in the insulating layer 60 so as to be electrically connected to the internal layer circuits 50. The conductive vias are composed of through-holes 61a and a conductive material 61b filled in the through-holes 61a, that is, metal.

Next, the external layer circuits 70 are formed on the insulating layer 60, the external layer circuits 70 being electrically connected to the internal layer circuits 50 through the conductive vias and constructing predetermined circuit patterns.

The external layer circuits 70 may be also formed through an electroless plating or electroplating method using SAP.

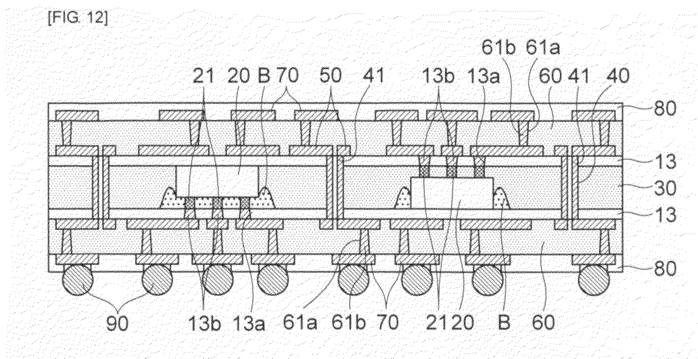

Then, as shown in FIG. 12, a protective layer 80 is formed on the insulating layer 60 so as to protect the external layer circuits 70.

That is, solder resist is applied on the insulating layer 60 so as to cover the external layer circuits 70, thereby forming the protective layer 80.

Further, to mount or install the PCB on an external device, external connection portions 90 such as solder bumps are formed on the external layer circuits 70.

In this case, portions of the protective layer 80 where the external connection portions 90 are to be respectively formed may be exposed by an etching process such that the external connection portions 90 are electrically connected to the external circuits 70.

That is, after the protective layer 80 is formed, the external layer circuits 70 corresponding to the portions of the protective layer 80, where the external connection portions 90 are to be respectively formed, are exposed to the outside through the etching process. Then, as the external connection portions 90 such as solder bumps are formed on the external circuits 70 exposed to the outside of the protective layer 80, the manufacturing of the PCB having electronic components embedded therein according to the embodiment of the invention is completed.

Meanwhile, in the state of FIG. 7, only the carrier copper foils 11 may be removed from the copper foil layers laminated on and under the core layer 30, and the thin copper foils 12 may not be removed so as to form the internal layer circuits 50 through an electroless plating or electroplating method using MSAP, the internal layer circuits 50 being electrically connected to the electronic components 20 and constructing predetermined circuit patterns.

In the PCB having electronic components embedded therein according to the embodiment of the invention, since the resin layer 13 is directly laminated on the core layer 30, the circuits which are connected to the I/O terminals for electrical connection of the electronic components can be formed on the resin layer 13. Therefore, an unnecessary insulating layer does not need to be further laminated on the core layer 30 having the electronic components 20 embedded therein.

Therefore, it is possible to reduce the number of layers of the PCB having electronic components embedded therein according to the embodiment of the invention. Accordingly, the manufacturing process can be simplified, and mass production can be achieved. Further, high density and high integration can be realized.

According to the present invention, the number of layers of the PCB can be reduced to thereby simplify the manufacturing process and to achieve mass production.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of manufacturing a PCB having electronic components embedded therein, comprising:
preparing a copper foil layer including a thin copper foil coated with a resin layer;
fixing electronic components onto the resin layer;
forming a core layer in which the electronic components are embedded;
forming internal layer circuits which are electrically connected to the electronic components;
forming an insulating layer on the internal layer circuits; and
forming external layer circuits on the insulating layer such that the external layer circuits are electrically connected to the internal layer circuits.

2. The method according to claim 1, wherein the copper foil layer includes a carrier copper foil for facilitating handling and the thin copper foil which is formed on the carrier copper foil and is coated with the resin layer.

3. The method according to claim 1, wherein the electronic components are fixed onto the resin layer of the copper foil layer through a bonding method using die bonder.

4. The method according to claim 1, wherein the forming of the core layer includes:
laminating an insulating material on the resin layer, the insulating material having cavities corresponding to the electronic components; and
laminating another copper foil layer corresponding to the copper foil layer on the insulating material such that the electronic components are buried by the insulating material.

5. The method according to claim 4, wherein the insulating material includes prepreg.

6. The method according to claim 1, wherein the forming of the internal layer circuits includes:
removing the thin copper foil; and
forming the internal layer circuits on the resin layer through SAP such that the internal layer circuits are electrically connected to the electronic components.

7. The method according to claim 1, wherein the forming of the internal layer circuits includes:
forming the internal layer circuits on the resin layer through MSAP by using the thin copper foil such that the internal layer circuits are electrically connected to the electronic components.

8. The method according to claim 6, wherein the forming of the internal layer circuits further includes:
forming conductive vias which electrically connect the internal layer circuits which are positioned in different layers.

9. The method according to claim 1, further comprising:
forming a protective layer on the insulating layer, the protective layer serving to protect the external layer circuits, after the forming of the external layer circuits; and
forming external connection portions which are electrically connected to the external layer circuits.

10. The method according to claim 1, wherein the protective layer is formed of solder resist.

11. The method according to claim 9, wherein the forming of the external connection portions includes:
exposing the external layer circuits to the outside of the protective layer, the external layer circuits being electrically connected to the external connection portions; and
forming the external connection portions on the external layer circuits exposed to the outside of the protective layer.

12. The method according to claim 9, wherein the external connection portions include solder bumps.
